(19) United States
(12) Patent Application Publication
(10) Pub. No.: US 2018/0040795 A1
(43) Pub. Date: Feb. 8, 2018

(54) Fluid Cooler / Heater

(71) Applicant: Novical, LLC, St. Paul, MN (US)

(72) Inventors: Luke Kwok Tung Lam, North Oaks, MN (US); Christopher Carl Stancer, Prescott, WI (US)

(21) Appl. No.: 15/654,337

(22) Filed: Jul. 19, 2017

Related U.S. Application Data
(60) Provisional application No. 62/371,933, filed on Aug. 8, 2016.

(51) Int. Cl. H01L 35/30; H01L 35/32; H01L 35/34

(52) U.S. Cl. CPC H01L 35/30; H01L 35/34; H01L 35/325; F24H 9/0021

(57) ABSTRACT

An example electrically powered fluid cooler can include: a housing with a receptacle into which a container including a fluid is received, the receptacle including a bottom and a side; a power source; and one or more Thermal Electric Cooler (TEC) units, with at least a first TEC unit of the one or more TEC units being positioned at the side or the bottom of the receptacle.

### RELATED APPLICATION(S)

This patent application claims the benefit of U.S. Patent Application Ser. No. 62/371933 filed on Aug. 8, 2016, the entirety of which is hereby incorporated by reference.

### BACKGROUND

Various methods and devices for heating and cooling of fluids are known but are specific to an application. In the application of using an outdoor cooking device such as a grill (a framework of materials used for cooking food over a heat source) or stove, there have been no unique or elegant solutions for maintaining a specific temperature of a fluid such as a beverage for drinking while utilizing that apparatus. The present invention discloses methods for cooling (or heating) fluids (such as consumable beverages like soda pop, juice, water, etc.) in conjunction with using these types of cooking devices.

### SUMMARY

In one aspect, an electrically powered fluid cooler includes: a housing defining a receptacle into which a container including a fluid is received, the receptacle including a bottom and a side; a power source; and one or more Thermal Electric Cooler (TEC) units, with at least a first TEC unit of the one or more TEC units being positioned at the side or the bottom of the receptacle.

In another aspect, an electrically powered drink cooler includes: a housing defining a receptacle into which a cup including a drink is received, the receptacle including a bottom and a side, wherein the housing is mounted to a grill; a power source including at least one Thermal Electric Generator (TEG) positioned at the grill to use grill waste heat to generate power; and at least one Thermal Electric Cooler (TEC) unit powered by the power from the TEG.

### DESCRIPTION OF THE DRAWINGS

FIG. 1a shows an example grill with a drink cooler in a first position thereon.

FIG. 1b shows an example grill with a drink cooler in a second position thereon.

FIG. 1c shows an example grill with a drink cooler in a third position thereon.

FIG. 1d shows an example grill with a drink cooler in a fourth position thereon.

FIG. 2a shows a perspective view of one example of the drink cooler of FIG. 1a.

FIG. 2b shows a top view of the drink cooler of FIG. 2a.

FIG. 2c shows a bottom view of the drink cooler of FIG. 2a.

FIG. 2d shows a front view of the drink cooler of FIG. 2a.

FIG. 2e shows a first side view of the drink cooler of FIG. 2a.

FIG. 2f shows a second side view of the drink cooler of FIG. 2a.

FIG. 2g shows a cross-sectional view of the drink cooler of FIG. 2a.

FIG. 2h shows an exploded view of the drink cooler of FIG. 2a.

FIG. 3 shows details of an example Thermal Electric Generator (TEG) of the drink cooler of FIG. 1a.

FIG. 4a shows a perspective view of another embodiment of a drink cooler including multiple Thermal Electric Cooling (TEC) units.

FIG. 4b shows a side view of the drink cooler of FIG. 4a.

FIG. 4c shows a top view of the drink cooler of FIG. 4a.

### DETAILED DESCRIPTION

This disclosure provides methods and devices for controlling the temperature of a fluid, such as a drink, by mounting the devices directly to a grill or through integration of the device in the original design of the grill. In some examples, a drink cooler can include but not be limited to, at least one Thermal Electric Cooler (TEC) utilizing the Peltier effect, and a power source. Optionally, cooling mechanisms such as heat sinks and a fan, along with temperature regulating electronics can be added to maximize the efficiency of the system.

In examples provided herein, a device is described that contains one or more TECs and other elements that mounts to a cooking grill. The cooking grill may be of a variety of types such as but not limited to gas, wood, electric, or charcoal heated. However, it is within the scope of this application that the device could optionally be mounted to other items and other locations such as, but not limited to: recreational vehicles (boats, campers, etc.); office settings (desks, cabinets, etc.); and/or sitting on top of such structures, work benches, etc. Furthermore, the cooling device can be configured to be used as chilling and heating devices in laboratory settings, such as for cooling and/or heating one or more fluids used in one or more chemical reactions.

The device includes elements to allow for controlling the temperature of the fluid. One component of the device is a thermally conductive receptacle that is optionally partially encased with an insulating member. This component with insulation creates a more efficient system by blocking ambient air from contacting the fluid.

The bottom or side of the receptacle is then mounted directly to one or more TECs through a variety of methods (mechanical fastener, pressure sensitive adhesive, or most efficiently through a thermal epoxy). Optionally, a heat sink and fan can be mounted on the other side of the TEC to help regulate the temperature of the TEC. This is achieved by the fan forcing air across the heat sink cooling fins further dissipating heat from the TEC hot side to the ambient air.

The cooling mechanism may also include direct conduction of heat from the TEC element to the thermally conductive grill shelf, to provide a much larger heat sink with a greater convective cooling surface area, or the combination of both mechanisms. One possible method for doing this would be direct contact of the hot side of the TEC with one of the metal surfaces of the grill.

Further embodiments of the device could include but not be limited to: a housing for protecting all of these interior elements, a switch for turning power to the TEC on and off, additional temperature regulating electronics to adjust power to the TEC to control temperature, another switch or one possibly integrated into the on/off switch that allows for reversal of the power to the TEC to switch from cooling a fluid to heating a fluid, and bracketry for mounting the device to a variety of surfaces, and the power source.

In the example of a heating device, the drink cooler can be configured such that current can be reversed so the TEC becomes a drink warmer (e.g., for coffee on a cold day). The electronics or a switch could reverse current through the TEC to create this desired effect. Further, an indicating light such as an LED (e.g., red) can be used to indicate that the drink cooler is warming a beverage, and another indicating light such as an LED or color (e.g., blue) to indicate that the drink cooler is cooling a beverage.

The power source for this TEC drink cooler may be provided using one or more techniques. A linear or switching power supply could be the primary source of power for converting AC power to DC current to power. This DC current can then drive the TEC, fan, and any additional electronics. As an example, this type of power supply can generate 12 Vdc and 5A commonly used for these types of electronics, although other voltages and currents can be used.

In addition to the primary source of power described above, one or more additional sources of power can be used in addition to or in place of the primary source, as applicable. One example of another source of power is commercially available solar cells/panels sufficient to generate the correct voltage and current. For example, one or more solar panels can be exposed to light and thereby provide a current to power the fluid cooler.

Further, the drink cooler can be configured to run on other sources of power, such as a 12 Vdc power adapter from a car/boat/etc.

In addition to power sources, a rechargeable battery can be provided to capture power from one or more of the power sources (e.g., a Thermal Electric Generator (TEG)) and store that power until needed. For example, the rechargeable battery can be used to store electricity that is generated by the TEG as the grill is used, and the stored electricity can be used to power the drink cooler when needed.

Further, a battery backup can be provided that is capable of powering the TEC for some time if the primary power method is interrupted, then charged once the primary power method is restored. This battery could be lithium ion or lead acid, but is not limited to those.

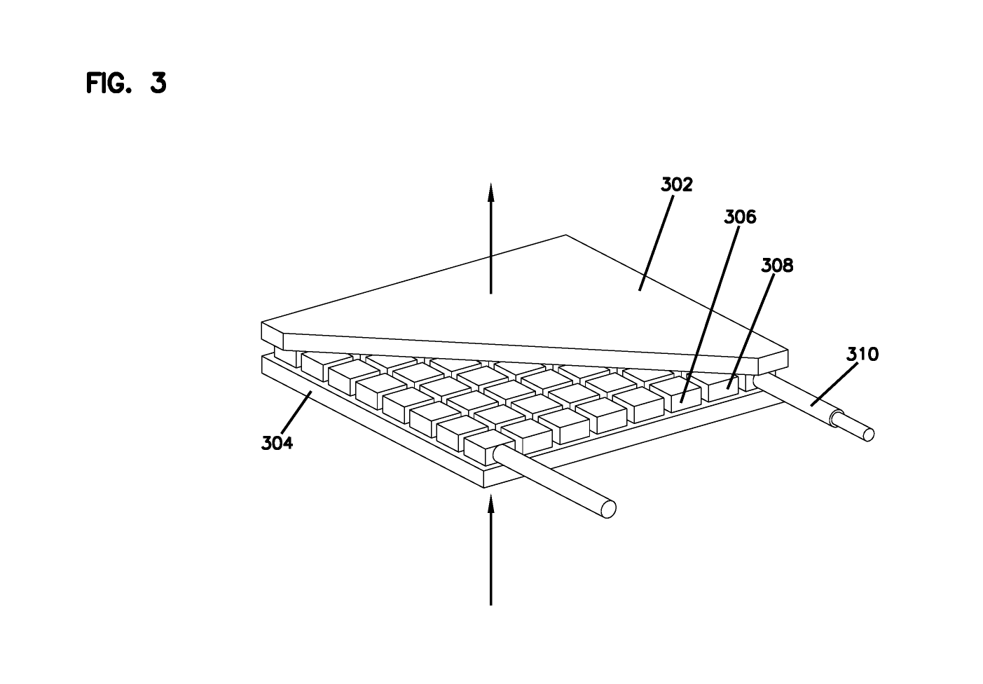

Another example source of power is the TEG (see FIG. 3) that uses the excess heat provided by the grill to generate electricity. This electricity can, in turn, be used to power the TEC drink cooler. Due to efficiency losses of thermal electric devices, the TEG could be much larger (e.g., 300 W) to power the smaller TEC (e.g., 60 W).

In some examples, the drink cooler 100 can include electronics to measure the temperature of the fluid cooler itself or the cup positioned within the drink cooler. With the temperature known, the drink cooler electronics are configured to regulate current flow through the TEC, to maintain a constant temperature of the fluid. Current regulation can be analog or digital (e.g., using pulse width modulation to switch power on and off or continuous modulation as determined by cooling needs).

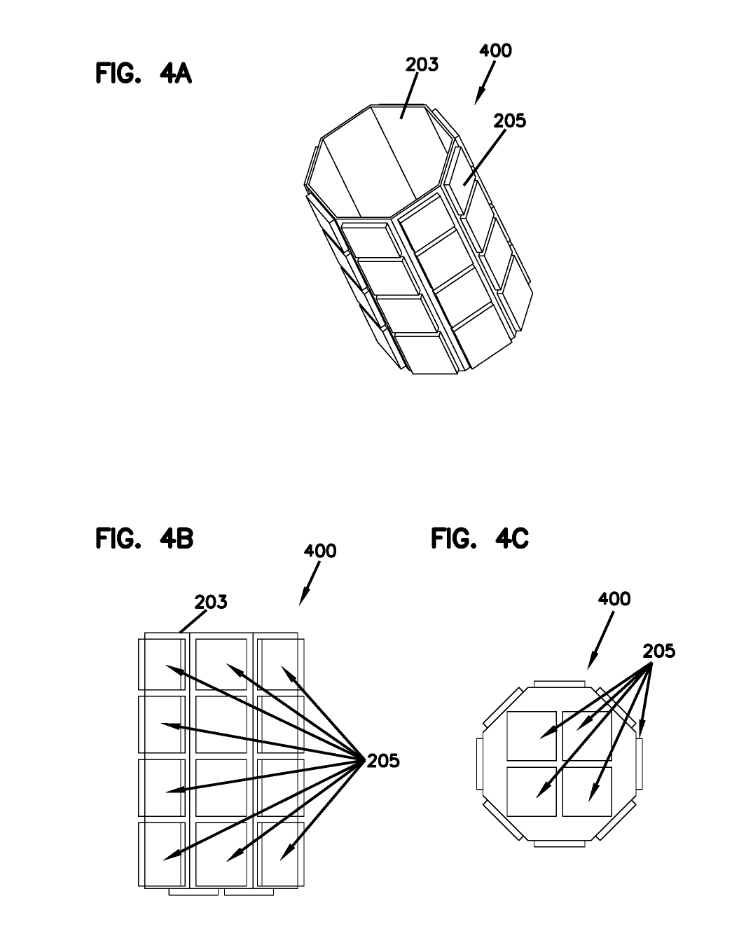

The drink cooler is also not limited to the utilization of a single TEC. Other embodiments can include additional TEC units (see FIGS. 4a-4c). These additional TEC units can be placed in a variety of locations such as, but not limited to, additional units placed on the bottom of the receptacle, units mounted around the perimeter of the receptacle, and potentially mounted on the top of an enclosed device.

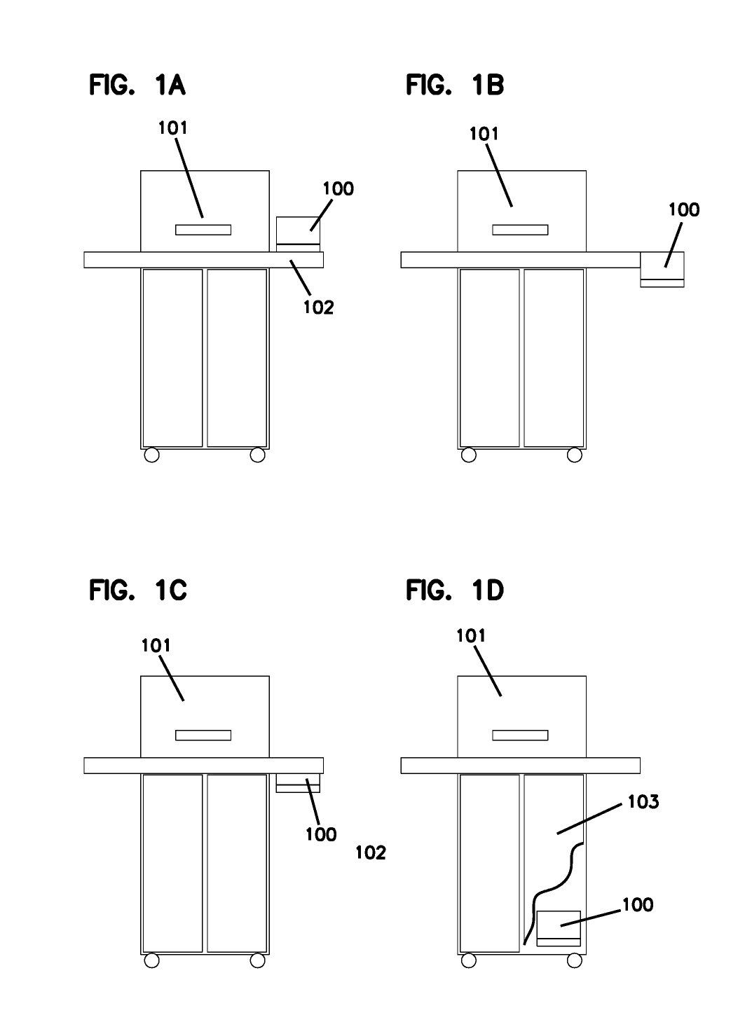

Referring now to the drawings, FIG. 1a shows an example grill 101 with one or more shelves 102. In this example, the grill 101 is a gas grill, although a charcoal grill or electric grill could also be used. Attached to the grill 101 or shelves 102 is a drink cooler 100. The drink cooler 100 can be configured as described below. In this example, the drink cooler 100 allows the user of the grill 101 to place a drink (e.g., a cup, bottle, or can, such as soda or beer) into the drink cooler 100 to keep the drink cool as the user uses the grill 101.

As noted, the drink cooler 100 can be provided as an accessory that is added to the grill 101. For example, the drink cooler 100 can be mounted through a hole in a shelf (e.g., one or more of shelves 102) of the grill 101, hang off the side of the grill shelf 102, attached by magnets, screws, brackets, and/or two sided tape, or sit right on the grill table top itself.

FIG. 1b shows the drink cooler 100 attached to the side of one of the grill's shelves 102.

FIG. 1c shows the drink cooler 100 integrally designed into one of the grill's shelves 102. Other configurations are possible.

FIG. 1d shows a break away view of the drink cooler 100 on the inside 103 of the grill 101.

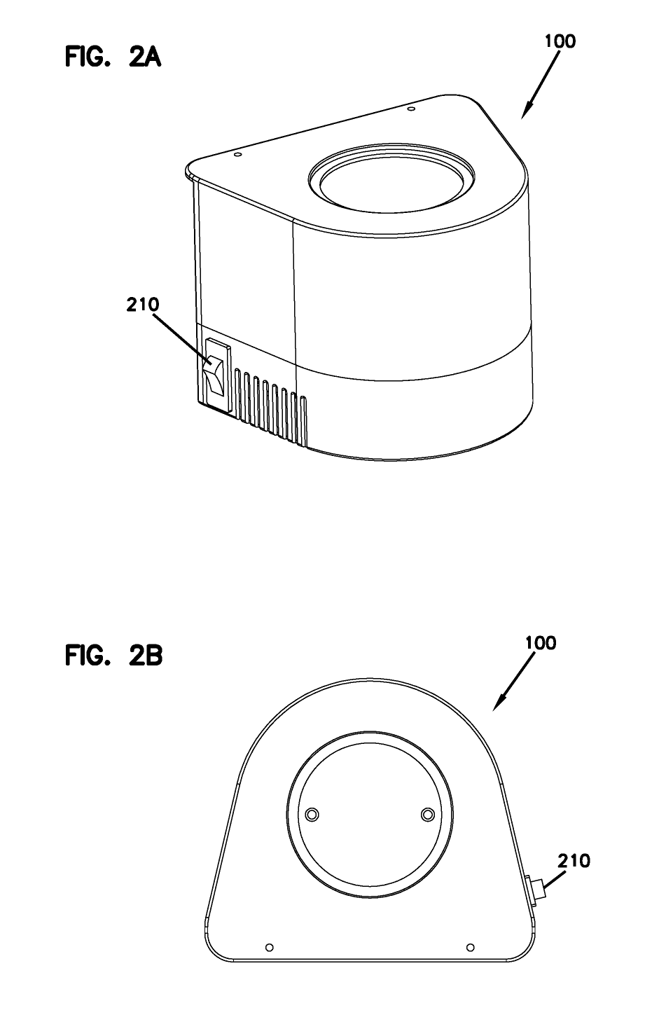

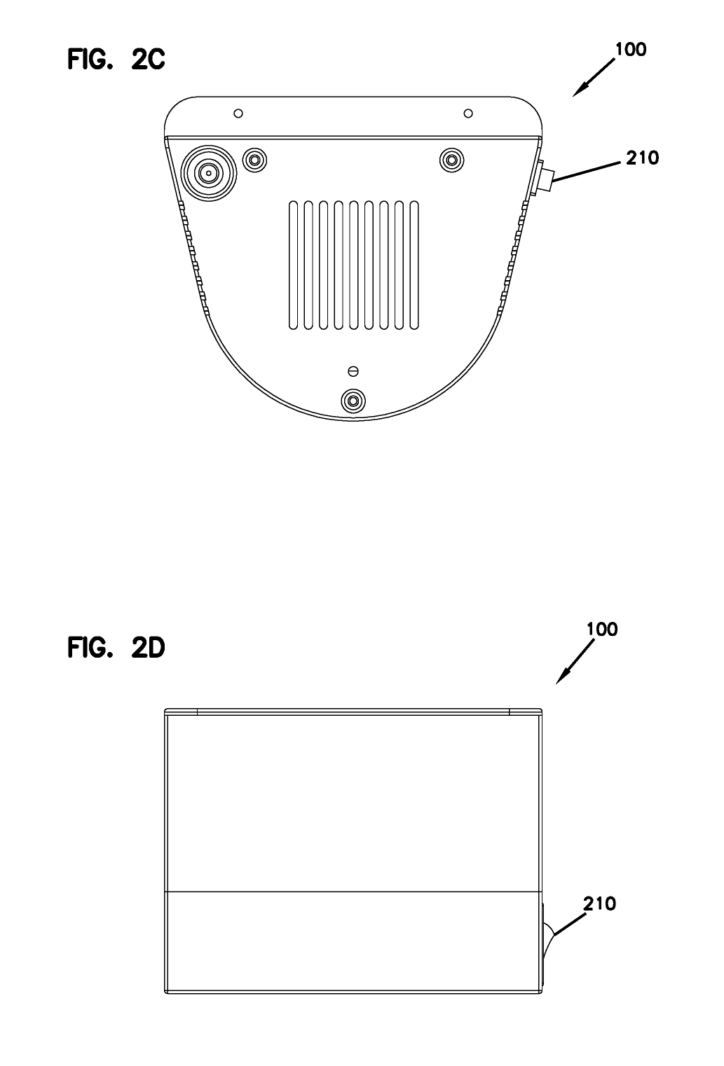

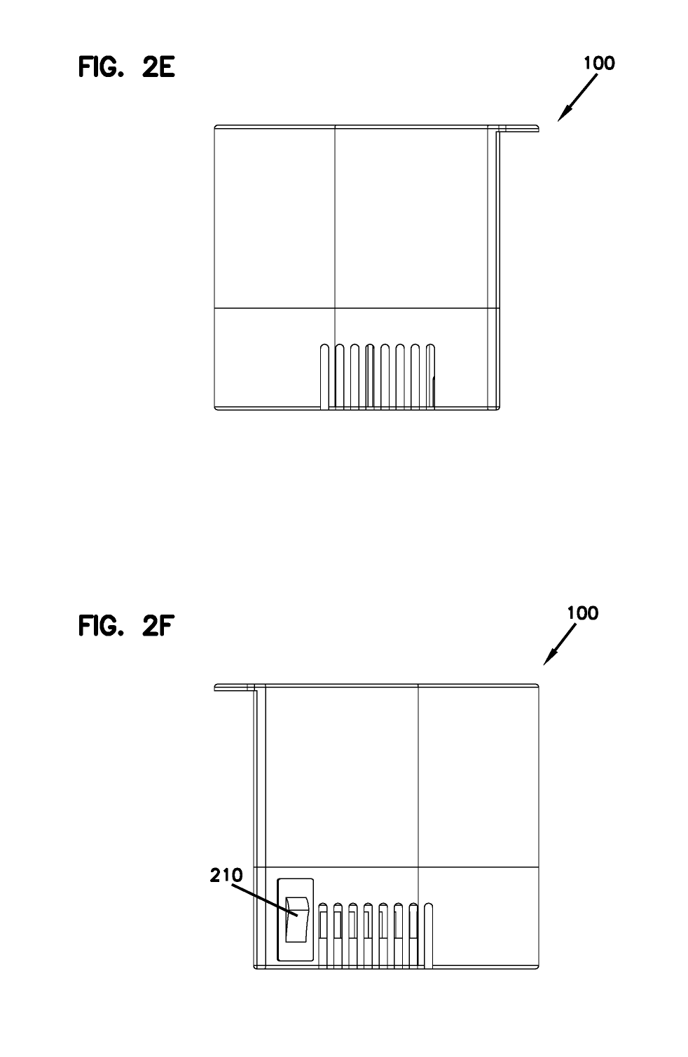

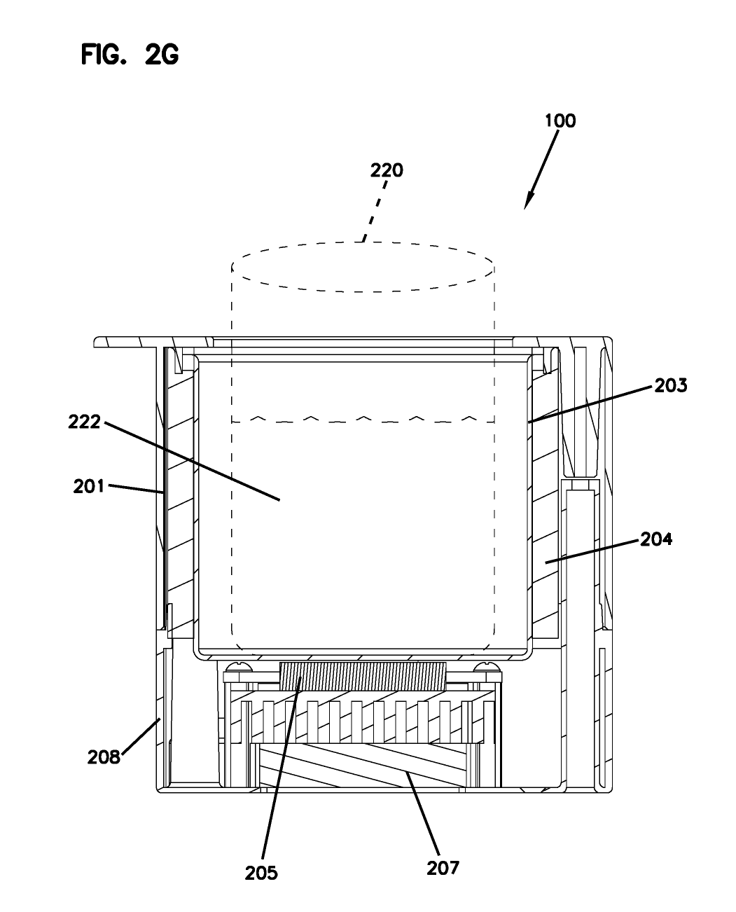

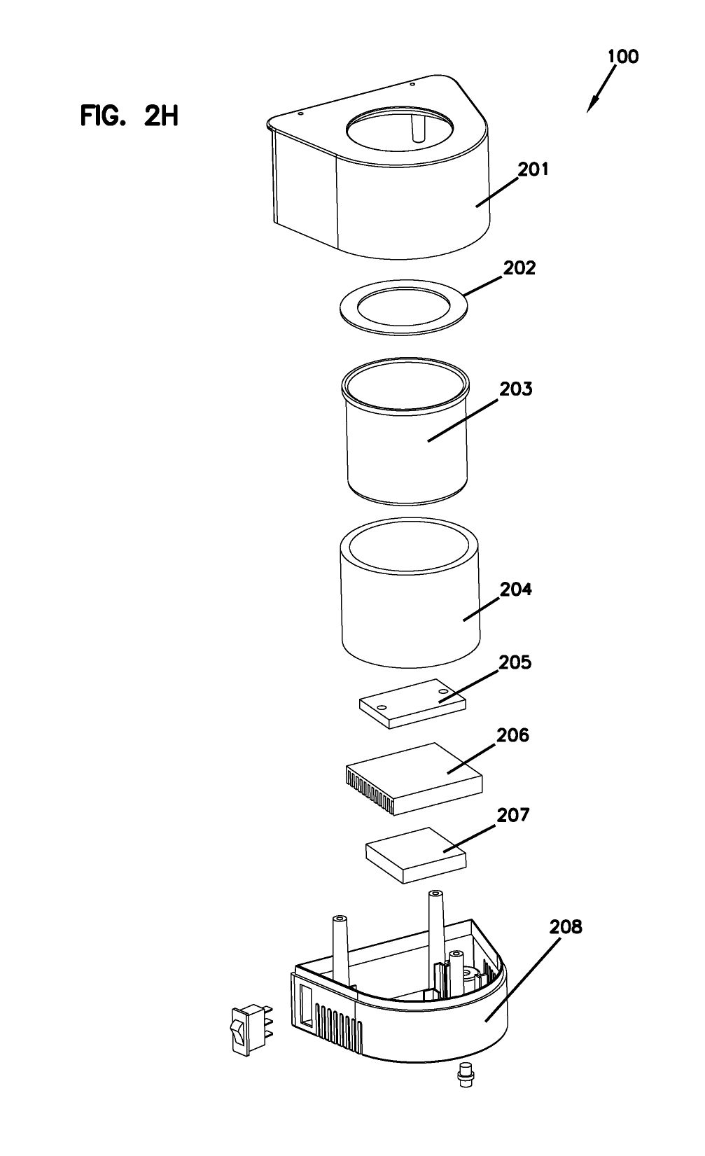

FIGS. 2a-2h show the example drink cooler 100 in an isometric view, orthographic projections, a section view, and in an exploded assembly view. The drink cooler optionally includes a top housing 201 and a bottom housing 208. A receptacle 203 and insulator 204 are positioned within the top and bottom housings 201, 208 and is sized to receive a cup or can 220 or other container holding a liquid 222 (e.g., a drink).

An optional seal 202 is positioned between the receptacle 203 and the top housing 201 to minimize moisture (e.g., from the drink) from entering an interior of the drink cooler 100. The seal 202 could be made from a variety of materials including a soft, flexible foam or rubber material cut appropriately to be able to flex and accept a variety of sizes of containers.

Also included in the exploded view is an optional heat sink 206 and fan 207 for further dissipating heat in the system for improved efficiency. An example TEC unit 205 is positioned between the heat sink 206 and is positioned to engage the cup once the cup is positioned with the drink cooler 100. An optional switch 210 can be provided for turning the drink cooler 100 on and off.

FIG. 3 shows additional details of the example TEC unit 205. In this example, the heat generated/displaced by the drink cooler 100 is conducted to the hot side, where a cooling mechanism then dissipates this heat to a number of areas such as ambient air or directly to the grill surfaces (i.e., forming a heat sink).

Specifically, the example TEC unit 205 includes two ceramic substrates 302, 304 that sandwich a plurality of P-type and N-type semiconductor pellets therebetween. Conduits 310 are configured to provide power (when the TEC unit 205 is used as a TEC) and to conduct current to a desired destination (when the TEC unit 205 is used as a TEG).

FIG. 4 shows one particular embodiment of a drink cooler 400 configured with multiple TEC units 205. In this specific example, the receptacle 203 (which is sized to hold the drink), is shaped in an octagon (although many other shapes and sizes can be used, such as round, square, rectangle, etc.) and has four TEC units 205 per side plus four additional TEC units 205 on the base or bottom of the receptacle for a total of 36 TEC units 205. More or fewer TEC units 205 could be used. In this example, at least one of the TEC units 205 (e.g., in one side) is mounted at an angle (e.g., 180 degrees) relative to another of the TEC units 205 (e.g., in another side). In another example, the one TEC unit 205 (e.g., in a side) is positioned at a 90 degree angle relative to another TEC unit 205 (e.g., in the bottom). Other configurations, such as TEC units mounted at other angles, are also possible.

What is claimed is:

1. An electrically powered fluid cooler, comprising:
a housing defining a receptacle into which a container including a fluid is received, the receptacle including a bottom and a side;
a power source; and
one or more Thermal Electric Cooler (TEC) units, with at least a first TEC unit of the one or more TEC units being positioned at the side or the bottom of the receptacle.

2. The electrically powered fluid cooler of claim 1, wherein the electrically powered fluid cooler includes a cooling side of the one or more TEC units connected to the receptacle.

3. The electrically powered fluid cooler of claim 1, wherein the electrically powered fluid cooler includes a cooling mechanism connected to a hot side of the one or more TEC units.

4. The electrically powered fluid cooler of claim 1, wherein the electrically powered fluid cooler is configured to be mounted to a cooking grill.

5. The electrically powered fluid cooler of claim 1, wherein the first TEC unit being positioned at the side or bottom, and further comprising at least a second TEC unit of the one or more TEC units being positioned at the bottom or the side of the receptacle.

6. The electrically powered fluid cooler of claim 1, wherein at least one of the one or more TEC units is mounted at an angle relative to another of the one or more TEC units.

7. The electrically powered fluid cooler of claim 1, wherein the power source includes an AC power adapter, solar panels, or a Thermal Electric Generator (TEG) driven by grill waste heat to power the electrically powered fluid cooler.

8. The electrically powered fluid cooler of claim 7, wherein multiple power sources may be used simultaneously to power the electrically powered fluid cooler.

9. The electrically powered fluid cooler of claim 1, further comprising electronics configured to measure a temperature of the fluid in the container positioned within the electrically powered fluid cooler or the temperature of the electrically powered fluid cooler and to maintain a constant cooling temperature.

10. The electrically powered fluid cooler of claim 1, further comprising a battery backup.

11. The electrically powered fluid cooler of claim 1, further comprising the electrically powered fluid cooler being externally mounted to a grill shelf.

12. The electrically powered fluid cooler of claim 1, further comprising the electrically powered fluid cooler being integrally mounted to a grill shelf.

13. The electrically powered fluid cooler of claim 1, further comprising the electrically powered fluid cooler being mounted internally to a grill.

14. The electrically powered fluid cooler of claim 1, further comprising the electrically powered fluid cooler being integrally mounted internally to a grill.

15. An electrically powered drink cooler, comprising:
a housing defining a receptacle into which a cup including a drink is received, the receptacle including a bottom and a side, wherein the housing is mounted to a grill;
a power source including at least one Thermal Electric Generator (TEG) positioned at the grill to use grill waste heat to generate power; and
at least one Thermal Electric Cooler (TEC) unit powered by the power from the at least one TEG.

16. The electrically powered drink cooler of claim 15, wherein the at least one TEC unit includes a plurality of Thermal Electric Cooler (TEC) units powered by the power from the at least one TEG, with at least a first of the plurality of TEC units being positioned at the side or the bottom of the receptacle.

17. The electrically powered drink cooler of claim 15, wherein the at least one TEC unit being positioned at the side or bottom, and further comprising at least a second TEC unit of the one or more TEC units being positioned at the bottom or the side of the receptacle.

18. The electrically powered drink cooler of claim 15, further comprising the electrically powered drink cooler being externally mounted to a grill shelf.

19. The electrically powered drink cooler of claim 15, further comprising the electrically powered drink cooler being integrally mounted to a grill shelf.

20. The electrically powered drink cooler of claim 15, further comprising the electrically powered drink cooler being mounted internally to the grill.
